(19) United States
(12) Patent Application Publication
(10) Pub. No.: US 2015/0097180 A1
(43) Pub. Date: Apr. 9, 2015

(54) IMAGE SENSOR AND METHOD OF MANUFACTURING THE SAME

(71) Applicant: Rayence Co., Ltd., Gyeonggi-do (KR)

(72) Inventors: Gyo Sun YU, Gyeonggi-do (KR); Myeong Ho KIM, Incheon (KR); Jin Hyeong PARK, Daejeon (KR); SEUNG IK JUN, Gyeonggi-do (KR); Duck Kyun CHOI, Seoul (KR)

(21) Appl. No.: 14/455,846

(22) Filed: Aug. 8, 2014

(30) Foreign Application Priority Data
Aug. 8, 2013 (KR) 10-2013-0094024

(51) Int. Cl. H01L 27/146; H01L 29/786

(52) U.S. Cl. CPC H01L 27/14616; H01L 27/14643; H01L 27/14623; H01L 29/7869; H01L 29/78618; H01L 27/14689; H01L 27/14692; H01L 27/14696; H01L 27/14685
USPC 257/43; 438/85

(57) ABSTRACT

The present invention provides an image sensor including an oxide semiconductor layer formed on a gate electrode, an oxide film formed on a surface of a channel region of the oxide semiconductor layer, source and drain electrodes formed on the oxide semiconductor layer and spaced apart from each other with the channel region interposed therebetween, an anti-etching film formed on the source and drain electrodes and configured to cover the oxide film, and a photodiode connected to the drain electrode.

### BACKGROUND OF THE INVENTION

1. Field of the Invention

The present invention relates, in general, to image sensors and, more particularly, to an image sensor including a thin film transistor that adopts an oxide semiconductor and a method of manufacturing the image sensor.

2. Description of the Related Art

In the past, schemes using a film and a screen were used in medical or industrial X-ray imaging. In this case, due to problems related to the development and storage of an imaged film, such schemes are inefficient from the standpoint of cost and time.

In order to improve such inefficiency, digital-type image sensors have been currently and widely used. Digital-type image sensors may be classified into a Charge Coupled Device (CCD) type, a Complementary Metal-Oxide-Semiconductor (CMOS) type, a Thin Film Transistor (TFT) type, etc.

Here, a TFT type is a scheme that uses a TFT substrate and is advantageous in that an image sensor can be manufactured to have a large area. In such a TFT-type image sensor, a Thin Film Transistor (TFT) and a photodiode are formed in each of the pixels arranged in a matrix.

Generally, as a semiconductor layer of a TFT, amorphous silicon is used. However, amorphous silicon is not better than crystal silicon in terms of electrical characteristics such as mobility.

In order to improve such a disadvantage, a scheme using an oxide semiconductor has recently been proposed. An oxide semiconductor is advantageous in that it has mobility characteristics that are several times to a dozen or more times higher than those of the amorphous silicon, and has off current characteristics better than those of the amorphous silicon.

In an image sensor that uses an oxide semiconductor, a photodiode is formed after an oxide semiconductor layer is formed. Upon forming the photodiode, a problem arises in that a channel region of the oxide semiconductor layer exposed between a source electrode and a drain electrode is damaged by an etching gas in an etching process, thus deteriorating electrical characteristics.

### SUMMARY OF THE INVENTION

Accordingly, the object of the present invention is to provide a scheme for preventing damage to an oxide semiconductor, thus improving electrical characteristics.

In order to accomplish the above object, the present invention provides an image sensor, including an oxide semiconductor layer formed on a gate electrode; an oxide film formed on a surface of a channel region of the oxide semiconductor layer; source and drain electrodes formed on the oxide semiconductor layer and spaced apart from each other with the channel region interposed therebetween; an anti-etching film formed on the source and drain electrodes and configured to cover the oxide film; and a photodiode connected to the drain electrode.

Here, the anti-etching film may be made of silicon nitride.

The photodiode may include a first electrode extended from the drain electrode; a semiconductor layer formed on the first electrode; and a second electrode formed on the semiconductor layer.

The semiconductor layer may include an n+ layer, an i layer, and a p+ layer sequentially located on the first electrode.

The image sensor may further include a protective layer formed on the anti-etching film and the photodiode, and configured to include a first contact hole for exposing the source electrode and a second contact hole for exposing the second electrode; and a readout line, a bias electrode and a black matrix formed on the protective layer, wherein the readout line is connected to the source electrode through the first contact hole, the bias electrode is connected to the second electrode through the second contact hole, and the black matrix is configured to cover the channel region.

The anti-etching film may have a thickness of 200 nm or more.

In accordance with another aspect, the present invention provides a method of manufacturing an image sensor, including forming an oxide semiconductor layer on a gate electrode; forming source and drain electrodes, spaced apart from each other with a channel region of the oxide semiconductor layer interposed therebetween, on the oxide semiconductor layer; forming an oxide film on a surface of the channel region of the oxide semiconductor layer; forming an anti-etching film that covers the oxide film, on the source and drain electrodes; and forming a photodiode connected to the drain electrode.

Here, the anti-etching film may be made of silicon nitride.

The oxide film may be formed via oxygen annealing.

The method may further include, before forming the oxide film, performing N₂O plasma treatment on the channel region of the oxide semiconductor layer.

The photodiode may include a first electrode extended from the drain electrode; a semiconductor layer formed on the first electrode; and a second electrode formed on the semiconductor layer.

The semiconductor layer may include an n+ layer, an i layer, and a p+ layer sequentially formed on the first electrode.

The method may further include forming a protective layer on the anti-etching film and the photodiode, wherein the protective layer includes a first contact hole for exposing the source electrode and a second contact hole for exposing the second electrode; and forming a readout line, a bias electrode and a black matrix on the protective layer, wherein the readout line is connected to the source electrode through the first contact hole, the bias electrode is connected to the second electrode through the second contact hole, and the black matrix is configured to cover the channel region.

The anti-etching film may have a thickness of 200 nm or more.

### ADVANTAGEOUS EFFECTS

According to the present invention, the anti-etching film that covers the channel region of the oxide semiconductor layer is formed on the source electrode and the drain electrode. Accordingly, the oxide semiconductor layer is prevented from being exposed to an etching gas in the photodiode formation process, thus preventing electrical characteristics from being deteriorated.

Further, the oxide film is formed on the surface of the channel region of the oxide semiconductor layer. Accordingly, together with the anti-etching film, the channel region of the oxide semiconductor layer may be more effectively protected. In particular, when the anti-etching film is made of silicon nitride, a large amount of hydrogen that is generated is prevented from permeating into the channel region of the oxide semiconductor layer, thus improving the electrical characteristics of the oxide semiconductor layer.

Furthermore, before the oxide film is formed, N₂O plasma treatment may be performed on the channel region of the oxide semiconductor layer. By means of such N₂O plasma treatment, defects in the channel region of the oxide semiconductor layer may be eliminated, and thus the electrical characteristics of the oxide semiconductor layer may be improved.

### BRIEF DESCRIPTION OF THE DRAWINGS

FIG. 1 is a view schematically showing an imaging apparatus using an image sensor according to an embodiment of the present invention;

FIG. 2 is a sectional view schematically showing the pixel of an image sensor according to an embodiment of the present invention;

FIGS. 3A to 3D are sectional views showing a method of manufacturing an image sensor according to an embodiment of the present invention; and

FIGS. 4 to 6 are views respectively showing I-V graphs appearing when N₂O plasma treatment is not performed, when N₂O plasma treatment is performed, and when N₂O plasma treatment and oxygen annealing are performed.

### DESCRIPTION OF THE PREFERRED EMBODIMENTS

Hereinafter, embodiments of the present invention will be described in detail with reference to the attached drawings.

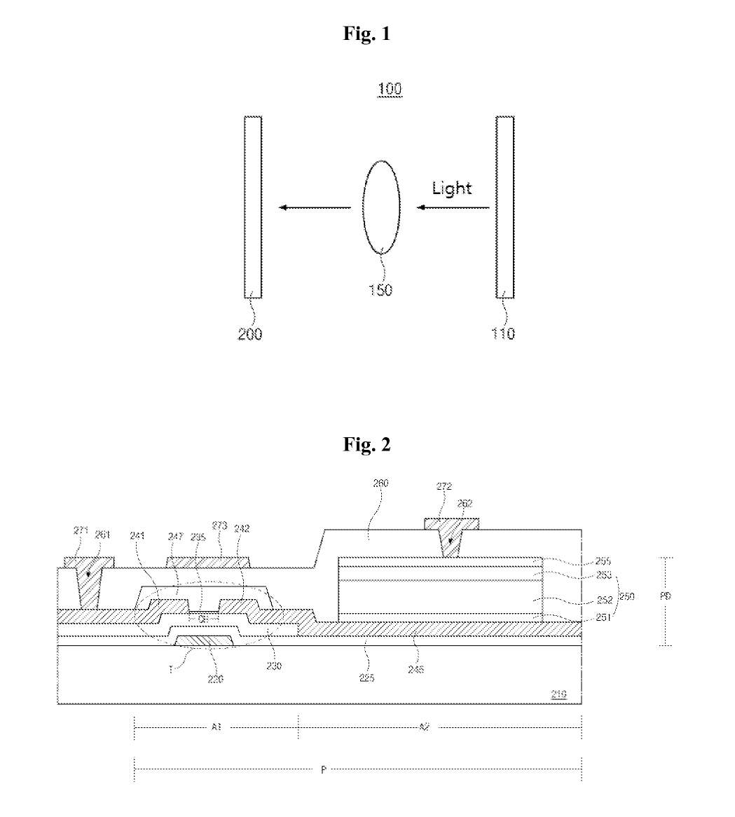

FIG. 1 is a view schematically showing an imaging apparatus using an image sensor according to an embodiment of the present invention, and FIG. 2 is a sectional view schematically showing the pixel of an image sensor according to an embodiment of the present invention.

Referring to FIG. 1, an imaging apparatus 100 according to an embodiment of the present invention includes a light generator 110 and an image sensor 200.

The light generator 110 corresponds to a component for generating light for imaging and radiating the light to a subject. For example, when X-ray imaging is performed, the light generator 110 generates and radiates X-rays.

The light radiated in this way passes through a subject 150 and is then incident on the image sensor 200. The image sensor 200 includes a plurality of pixels P arranged in a matrix.

Each pixel P includes a photodiode PD configured to convert the incident light into an electrical signal, and a thin film transistor T electrically connected to the photodiode PD and configured to perform an ON/OFF switching operation in response to a scan signal and output an electrical signal to a readout line 271.

The image sensor 200 that performs such a function will be described in greater detail with reference to FIG. 2.

Referring to FIG. 2, in each pixel P of the image sensor 200, the thin film transistor T and the photodiode PD are formed. For convenience of description, an area in which the thin film transistor T is formed is called a first area A1 and an area in which the photodiode PD is formed is called a second area A2.

On a substrate 210, a gate electrode 220 is formed. On the gate electrode 220, a gate insulating film 225 is substantially formed on the overall surface of the substrate 210.

The gate electrode 220 may be formed as a single-layer structure or a multi-layer structure. For example, the gate electrode may be formed as a dual-layer structure of molybdenum (Mo)/aluminum (Al).

On the gate insulating film 225, an oxide semiconductor layer 230 is formed to correspond to the gate electrode 220. The oxide semiconductor layer 230 may be made of one of, for example, Indium Gallium Zinc Oxide (IGZO), Zinc Tin Oxide (ZTO), and Zinc Indium Oxide (ZIO), but is not limited thereto.

An oxide film 235 is formed on the surface of a channel region CH of the oxide semiconductor layer 230. The oxide film 235 functions to protect the oxide semiconductor layer 230 in a subsequent process for forming an anti-etching film 247.

Such an oxide film 235 may be formed via, for example, an oxygen (O₂) annealing process.

Meanwhile, before the oxide film 235 is formed, N₂O plasma treatment may be performed on the channel region CH of the oxide semiconductor layer 230. By means of N₂O plasma treatment, defects in the channel region CH of the oxide semiconductor layer 230 are eliminated, thus improving film properties.

On the oxide semiconductor layer 230, a source electrode 241 and a drain electrode 242 spaced apart from each other are formed with the channel region CH interposed therebetween. Each of the source electrode 241 and the drain electrode 242 may be formed as a single-layer structure or a multi-layer structure. For example, each of the source and drain electrodes may be formed as a triple-layer structure of molybdenum (Mo)/aluminum (Al)/molybdenum (Mo).

The above-described gate electrode 220, oxide semiconductor layer 230, and source and drain electrodes 241 and 242 configured in the first area A1 form the thin film transistor T.

On the source and drain electrodes 241 and 242, an anti-etching film 247 covering the channel region CH of the oxide semiconductor layer 230 may be formed. Meanwhile, the anti-etching film 247 may be configured to at least partially overlap the source and drain electrodes 241 and 242.

The anti-etching film 247 functions to prevent the oxide semiconductor layer 230 from being influenced by an etching environment for the photodiode PD in a subsequent process for forming the photodiode PD. Such an anti-etching film 247 may be made of, for example, an inorganic insulating material, such as silicon oxide (SiO₂) or silicon nitride (SiNx).

The anti-etching film 247 may be formed to have a thickness of, for example, 100 nm or more, but is not limited thereto. More preferably, the anti-etching film 247 may be formed to have a thickness of 200 nm or more.

The drain electrode 242 extends to the second area A2. A portion formed to extend to the second area A2 in this way functions as the first electrode 245 of the photodiode PD. In this way, the photodiode PD may be electrically connected to the thin film transistor T through the first electrode 245.

A semiconductor layer 250 may be formed on the first electrode 245, and a second electrode 255 may be formed on the semiconductor layer 250.

Here, one of the first electrode 245 and the second electrode 255 functions as a cathode, and the other functions as an anode. For convenience of description, a case where the first electrode 245 functions as a cathode and the second electrode 255 functions as an anode is exemplified. In this case, the second electrode 255 may be made of a material having a higher work function than that of the first electrode 245, for example, one of transparent conductive materials such as indium-tin-oxide (ITO), indium-zinc-oxide (IZO), and indium-tin-zinc-oxide (ITZO).

A PIN-type photodiode, for example, may be used as the photodiode PD, but the PD is not limited to such an example. When the PIN-type photodiode is used, the semiconductor layer 250 may include an n+ layer 251, an i layer 252, and a p+ layer 253.

A projective layer 260 may be formed on the substrate 210 on which the photodiode PD is formed. Such a protective layer 260 may be substantially formed on the overall surface of the substrate 210. The protective layer 260 may be made of an inorganic insulating material, for example, silicon oxide (SiO₂) or silicon nitride (SiNx).

In the protective layer 260, a first contact hole 261 for exposing the source electrode 241 and a second contact hole 262 for exposing the second electrode 255 may be formed.

On the protective layer 260, a readout line 271 and a bias electrode 272 may be formed. The readout line 271 is connected to the source electrode 241 through the first contact hole 261. The bias electrode 272 is connected to the second electrode 255 through the second contact hole 262 to apply a bias voltage to the second electrode 255.

Each of the readout line 271 and the bias electrode 272 may be formed as single-layer structure or a multi-layer structure. For example, each of the readout line and the bias electrode may be formed as a triple-layer structure of molybdenum (Mo)/aluminum (Al)/molybdenum (Mo).

Meanwhile, when the readout line 271 and the bias electrode 272 are formed, a black matrix 273 made of the same material as the readout line and the bias electrode may be formed to correspond to the thin film transistor T. The black matrix 273 functions to prevent light from being incident on the channel region CH of the oxide semiconductor layer 230.

As described above, in accordance with the embodiment of the present invention, the anti-etching film 247 is formed so as to prevent the channel region CH of the oxide semiconductor layer 230 from being exposed to an etching gas and from being degraded in an etching process for forming the semiconductor layer 250 and second electrode 255 of the photodiode PD. Accordingly, the electrical characteristics of the oxide semiconductor layer 230 may be prevented from being deteriorated.

Furthermore, an oxide film 235 is formed on the surface of the channel region CH of the oxide semiconductor layer 230. Accordingly, together with the anti-etching film 247, the channel region CH of the oxide semiconductor layer 230 may be more effectively protected.

In particular, when the anti-etching film 247 is made of silicon nitride, a large amount of hydrogen (H₂) is generated compared to a case where silicon oxide is used, resulting in excessive damage to the oxide semiconductor layer 230. Therefore, the oxide film 235 is formed on the surface of the channel region CH of the oxide semiconductor layer 230, so that the permeation of hydrogen may be prevented, thus consequently improving the electrical characteristics of the oxide semiconductor layer 230.

Furthermore, if the thickness of the anti-etching film 247 is increased up to a permissible range, the permeation of hydrogen into the oxide semiconductor layer 230 due to the diffusion of hydrogen may be reduced.

Furthermore, before the oxide film 235 is formed, N₂O plasma treatment may be performed on the oxide semiconductor layer 230. By means of such N₂O plasma treatment, defects in the channel region CH of the oxide semiconductor layer 230 may be eliminated, and thus the electrical characteristics of the oxide semiconductor layer 230 may be improved.

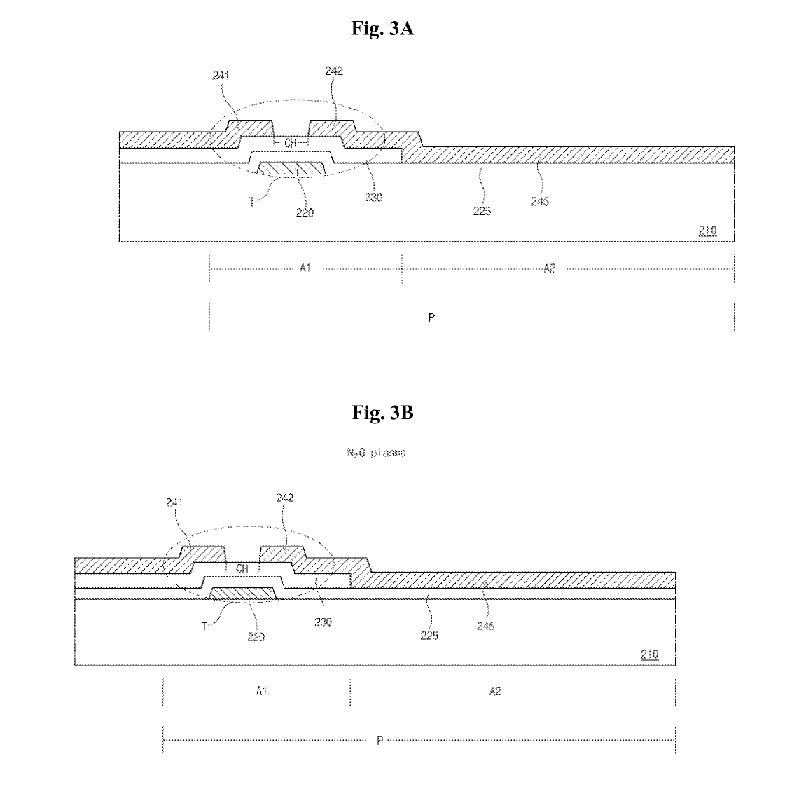

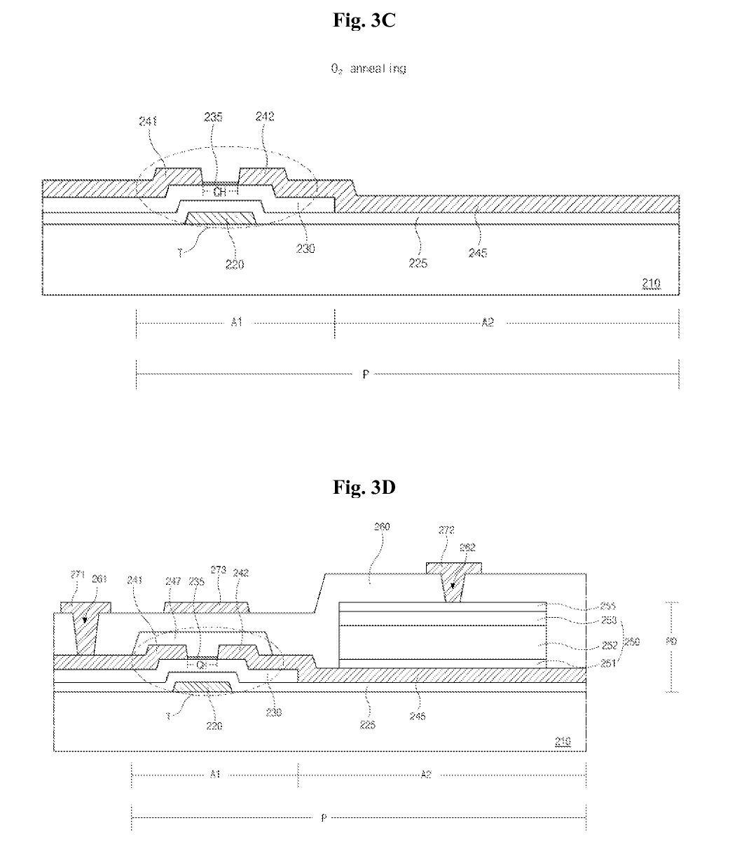

Hereinafter, a method of manufacturing an image sensor according to an embodiment of the present invention will be described in detail with reference to FIG. 3.

FIGS. 3A to 3D are sectional views showing a method of manufacturing an image sensor according to an embodiment of the present invention.

Referring to FIG. 3A, a gate electrode 220 is formed in a first area A1 by depositing a metal material on a substrate 210 and performing a mask process. Here, the mask process is a process for forming a thin film pattern, and denotes a series of processes including a photoresist deposition process, an exposure process, a development process, an etching process, a photoresist strip process, etc.

Next, a gate insulating film 225 is formed on the substrate 210 on which the gate electrode 220 is formed. Then, an oxide semiconductor layer 230 corresponding to the gate electrode 220 is formed by depositing an oxide semiconductor on the top of the gate insulating film 225 and performing a mask process.

Thereafter, a source electrode 241 and a drain electrode 242 are formed by depositing a metal material and performing a mask process. Meanwhile, the drain electrode 242 is formed to extend to the second area A2 of a pixel P in which a photodiode is to be formed. In this way, a portion formed in the second area A2 corresponds to a first electrode 245.

Referring to FIG. 3B, N₂O plasma treatment is performed on the substrate 210 on which the source and drain electrodes 241 and 242 are formed. Accordingly, the channel region CH of the oxide semiconductor layer 230 is N₂O plasma treated and then defects in the channel region may be eliminated and film properties may be improved. Meanwhile, as another example, N₂O plasma treatment may be performed before the source and drain electrodes 241 and 242 are formed after the oxide semiconductor material has been deposited.

Referring to FIG. 3C, oxygen (O₂) annealing is performed on the substrate 210 on which the source and drain electrodes 241 and 242 are formed. By means of such oxygen (O₂) annealing, an oxide film 235 is formed on the surface of the channel region CH of the oxide semiconductor layer 230.

Here, oxygen annealing may be performed, for example, for about 1 hour at a temperature of about 300° C., but it is not limited to such an example.

Referring to FIG. 3D, after an inorganic insulating material has been deposited on the substrate 210 on which the oxide film 235 is formed, a mask process is performed, and thus an anti-etching film 247 that covers the channel region CH is formed. Here, the inorganic insulating material may be deposited via, for example, a Plasma-Enhanced Chemical Vapor Deposition (PECVD) process.

Next, a semiconductor layer 250 and a second electrode 255 are formed on the first electrode 245. In relation to this, the semiconductor layer 250 composed of an n+ layer 251, an i layer 252, and a p+ layer 253 and the second electrode 255 are formed by sequentially depositing, for example, an n+ material, an i material, and a p+ material, depositing a transparent conductive material on the top of the p+ material layer, and then performing a mask process. Meanwhile, as another example, after the semiconductor layer 250 has been formed, the second electrode 255 may be formed by depositing a transparent conductive material and performing a mask process.

Next, a protective layer 260 is formed by depositing an inorganic insulating material on the substrate 210 on which the second electrode 255 is formed, and first and second contact holes 261 and 262 are formed by performing a mask process on the protective layer 260.

Then, a readout line 271 and a bias electrode 272 are formed by depositing a metal material on the protective layer 260 and performing a mask process. Meanwhile, a black matrix 273 may be formed over the thin film transistor T.

The readout line 271 is connected to the source electrode 241 through the first contact hole 261, and the bias electrode 272 is connected to the second electrode 255 of the photodiode PD through the second contact hole 262.

Meanwhile, the black matrix 273 is configured to cover the channel region CH and is then capable of preventing leakage current from being generated in the oxide semiconductor layer 230 due to light incidence.

Through the above-described processes, the image sensor according to the embodiment of the present invention may be manufactured.

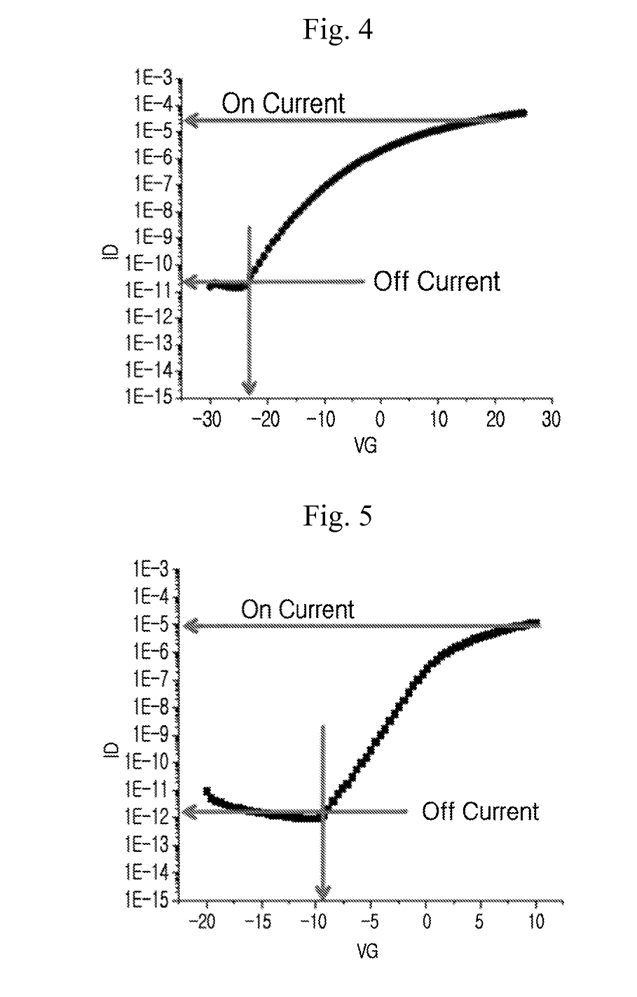

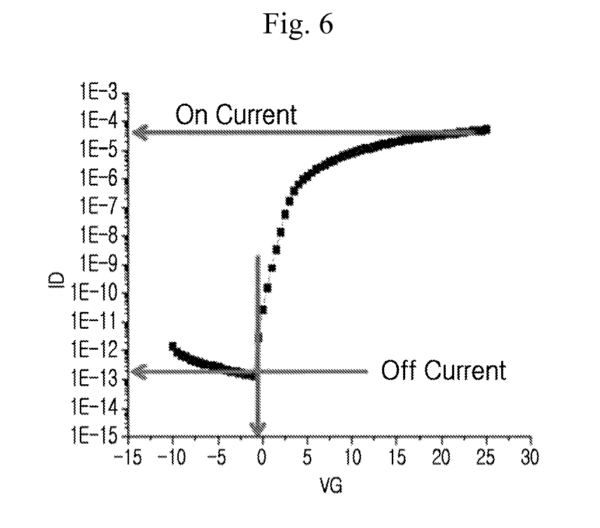

FIGS. 4 to 6 respectively illustrate I-V graphs appearing when N₂O plasma treatment is not performed, when N₂O plasma treatment is performed, and when N₂O plasma treatment and oxygen annealing are performed.

Referring to the drawings, it can be seen that Sub-threshold voltage Swing (S/S) characteristics, off current characteristics, and on/off ratio characteristics are improved upon performing N₂O plasma treatment, and are further improved upon performing both N₂O plasma treatment and oxygen annealing. In addition, mobility characteristics are also improved upon performing N₂O plasma treatment and are further improved upon performing both N₂O plasma treatment and oxygen annealing.

As described above, in accordance with the embodiment of the present invention, the anti-etching film that covers the channel region of the oxide semiconductor layer is formed on the source electrode and the drain electrode. Accordingly, the oxide semiconductor layer is prevented from being exposed to an etching gas in the photodiode formation process, thus preventing electrical characteristics from being deteriorated.

Further, the oxide film is formed on the surface of the channel region of the oxide semiconductor layer. Accordingly, together with the anti-etching film, the channel region of the oxide semiconductor layer may be more effectively protected. In particular, when the anti-etching film is made of silicon nitride, a large amount of hydrogen that is generated is prevented from permeating into the channel region of the oxide semiconductor layer, thus improving the electrical characteristics of the oxide semiconductor layer.

Furthermore, before the oxide film is formed, N₂O plasma treatment may be performed on the channel region of the oxide semiconductor layer. By means of such N₂O plasma treatment, defects in the channel region of the oxide semiconductor layer may be eliminated, and thus the electrical characteristics of the oxide semiconductor layer may be improved.

The above-described embodiments of the present invention are examples of the present invention and may be freely modified within the scope of the present invention included in the spirit of the invention. Therefore, the present invention includes modifications of the invention within the scope of the accompanying claims and equivalents thereof.

1. An image sensor, comprising:
an oxide semiconductor layer formed on a gate electrode;
an oxide film formed on a surface of a channel region of the oxide semiconductor layer;
source and drain electrodes formed on the oxide semiconductor layer and spaced apart from each other with the channel region interposed therebetween;
an anti-etching film formed on the source and drain electrodes and configured to cover the oxide film;
a photodiode connected to the drain electrode, wherein the photodiode includes a first electrode extended from the drain electrode, a semiconductor layer formed on the first electrode; and a second electrode formed on the semiconductor layer;
a protective layer formed on the anti-etching film and the photodiode, and configured to include a first contact hole for exposing the source electrode and a second contact hole for exposing the second electrode; and
a readout line, a bias electrode and a black matrix formed on the protective layer, wherein the readout line is connected to the source electrode through the first contact hole, the bias electrode is connected to the second electrode through the second contact hole, and the black matrix is configured to cover the channel region.

2. The image sensor of claim 1, wherein the anti-etching film is made of silicon nitride.

3. (canceled)

4. The image sensor of claim 1, wherein the semiconductor layer includes an n+ layer, an i layer, and a p+ layer sequentially located on the first electrode.

5. (canceled)

6. The image sensor of claim 1, wherein the anti-etching film has a thickness of 200 nm or more.

7. A method of manufacturing an image sensor, comprising:
forming an oxide semiconductor layer on a gate electrode;
forming source and drain electrodes, spaced apart from each other with a channel region of the oxide semiconductor layer interposed therebetween, on the oxide semiconductor layer;
performing N₂O plasma treatment on the channel region of the oxide semiconductor layer;
forming an oxide film on a surface of the channel region of the oxide semiconductor layer;
forming an anti-etching film that covers the oxide film, on the source and drain electrodes;
forming a photodiode connected to the drain electrode;
forming a protective layer on the anti-etching film and the photodiode, wherein the protective layer includes a first contact hole for exposing the source electrode and a second contact hole for exposing the second electrode; and
forming a readout line, a bias electrode and a black matrix on the protective layer, wherein the readout line is connected to the source electrode through the first contact hole, the bias electrode is connected to the second electrode through the second contact hole, and the black matrix is configured to cover the channel region.

8. The method of claim 7, wherein the anti-etching film is made of silicon nitride.

9. The method of claim 7, wherein the oxide film is formed via oxygen annealing.

10. (canceled)

11. The method of claim 7, wherein the photodiode comprises:
a first electrode extended from the drain electrode;
a semiconductor layer formed on the first electrode; and
a second electrode formed on the semiconductor layer.

12. The method of claim 11, wherein the semiconductor layer includes an n+ layer, an i layer, and a p+ layer sequentially formed on the first electrode.

13. (canceled)

14. The method of claim 7, wherein the anti-etching film has a thickness of 200 nm or more.
